(19) United States
(12) Patent Application Publication
(10) Pub. No.: US 2007/0073448 A1
(43) Pub. Date: Mar. 29, 2007

(54) Semiconductor device having a hole or a step of normal mesa shape as viewed from any cross-section and manufacturing method of the same

(75) Inventors: Chisaki Takubo, Kodaira (JP); Hiroji Yamada, Shiroyama (JP); Kazuhiro Mochizuki, Tokyo (JP); Kenichi Tanaka, Kodaira (JP); Tomonori Tanoue, Machida (JP); Hiroyuki Uchiyama, Musasimurayama (JP)

Correspondence Address: MATTINGLY, STANGER, MALUR & BRUNDIDGE, P.C., 1800 DIAGONAL ROAD, SUITE 370, ALEXANDRIA, VA, 22314, US

(73) Assignee: Renesas Technology Corp.

(21) Appl. No.: 11/583,885

(22) Filed: Oct. 20, 2006

Related U.S. Application Data
(63) Continuation of application No. 10/878,368, filed on Jun. 29, 2004, now Pat. No. 6,968,774.

(30) Foreign Application Priority Data
Aug. 19, 2003 (JP) 2003-207831

(51) Int. Cl. G05D 1/10

(52) U.S. Cl. 700/302

(57) ABSTRACT

A semiconductor device capable of overcoming a drawback due to the shape of a concave portion present in the zinc blende type compound semiconductor substrate in which the area of the bottom is larger than the surface in the cross sectional shape, as well as a manufacturing method thereof. A hole or step present in the semiconductor substrate constituting the semiconductor device is formed into a normal mesa shape irrespective of the orientation of the crystals on the surface of the semiconductor substrate. A wet etching solution having an etching rate for a portion below the etching mask higher than that in the direction of the depth of the semiconductor substrate is used.

### CROSS-REFERENCES

This application is a continuation application of U.S. Ser. No. 10/878,368, filed Jun. 29, 2004.

### CLAIM OF PRIORITY

The present application claims priority from Japanese Application JP 2003-207831 filed on Aug. 19, 2003, the content of which is hereby incorporated by reference into this application.

### BACKGROUND OF THE INVENTION

1. Field of the Invention

The present invention relates to a semiconductor device using a substrate of a zinc blende single crystal semiconductor, for example, GaAs and InP, as group III-V compound semiconductor.

2. Related Art

In recent years, along with rapid increase of the demand for mobile communication systems or optical communication systems, research and development have been conducted vigorously for semiconductor devices used for the communication systems. For example, a heterojunction bipolar transistor (HBT) having a hole on the rear face of a GaAs substrate as group a III-V single crystal semiconductor as a power amplifier has been reported in Japanese Patent Laid-open No. 6-5620 (Paragraph No. 0016, FIG. 1) and a collector top heterojunction bipolar transistor (C-top HBT) has been reported in Japanese Patent Laid-open No. 10-41320 (Paragraph No. 0006, FIG. 1).

In fabricating a substrate of a group III-V single crystal semiconductor such as GaAs, dry etching using a gas, wet etching using a liquid or etching using both of them in combination is generally used. In dry etching, the lateral surface of a hole or step is always nearly perpendicular to the surface of a substrate, and thus, an inverted mesa shape is not formed. However, in a case where the shape of the lateral wall is nearly vertical, it is difficult to form an electrode material on the lateral surface. If a step is large, disconnection may be possibly caused at the step. Further, it is difficult to control the end of dry etching at an accuracy of about several nanometers. On the other hand, in a case of conducting etching only by wet etching, etching can be stopped automatically by utilizing a layer of a substance having different selectivity. For example, this is a method of wet etching a GaAs layer with an etching solution containing an acid and aqueous hydrogen peroxide and stopping etching with an InGaP layer.

However, the following is well-known: in a case of etching a GaAs substrate by using an etching solution of a composition known so far and a mask material, the etching is stopped at {111} A crystal plane in which inverted mesa and normal mesa shapes are developed, failing to obtain necessary shape and depth. FIGS. 2, 3 and 4 show the shape of a hole by way of example when it is formed in a (100) plane 6 of a GaAs substrate 9. FIG. 2 is a perspective view of a GaAs crystal body 9 shown on the coordinate axis. FIG. 2 shows a positional relation between the crystal orientation of GaAs and a normal mesa shape 41 and a inverted mesa shape 42 formed generally. The normal mesa shape 41 is observed as viewed from a (01-1) plane 7 and the inverted mesa shape 42 is observed as viewed from a (011) plane 8 vertical to the (100) plane 6. In the present specification, “−1” for the surface index (01-1) is used in the following meanings. That is, in the field of the crystallography, when a certain plane crosses an axis on the negative side with respect to the original point, the index is negative and a negative sign is generally attached above the index. In the present specification however, the negative sign usually attached above the index is attached ahead of the index and indicated, for example, as “−1” in view of typestyle.

FIG. 3 is a cross-sectional view enlarging the hole of the normal mesa shape as viewed from a (01-1) plane of the GaAs substrate 9. An angle 11 formed between the lateral surface of a hole in which etching is stopped at a {111} A plane 10, and the substrate surface of a (100) plane 6 remaining on the outside of the hole opening is about 125.3°. In the same manner, FIG. 4 is a cross-sectional view enlarging the hole of the inverted mesa shape as viewed from a (011) plane of the GaAs substrate 9. An angle 13 formed between the lateral surface of a hole in which etching is stopped at the {111} A plane 10, and the (100) plane 6 on the substrate surface remained to the outside of the hole opening is about 54.7°. As described above, in the wet etching using an existent etching solution, the inverted mesa shape is developed depending on the crystal orientation. Accordingly, in a case of forming an electrode so as to extend over the inside and outside of the hole, disconnection may possibly occur at the inverted mesa portion. In the preparation of FET gates using the GaAs substrate, the layout is sometimes restricted so as not to lead out the electrode in the direction of the inverted mesa. Further, in a case of filling a conductive substance such as a silver paste in the hole and bonding to a module substrate, it cannot sometimes be filled completely to leave air in the inverted mesa portion to possibly cause bursting due to temperature elevation.

On the other hand, in the method of combining the dry etching and the wet etching, the wet etching is generally applied after the dry etching. Depending on the re-deposition place of reaction products between the dry etching gas and the etched substance, the reaction products act as a mask material to sometimes hinder the proceeding of the succeeding wet etching.

A technical subject of the present invention is to prevent occurrence of disconnection of electrodes caused by steps and bursting caused by residual air.

### SUMMARY OF THE INVENTION

The present invention intends to provide a semiconductor device capable of overcoming a drawback due to the shape of a concave portion present in a zinc blende type compound semiconductor substrate in which the area of the bottom is larger than the surface in the cross-sectional shape, as well as a manufacturing method thereof.

According to the invention, a hole or step present in a semiconductor substrate constituting the semiconductor device is formed into a normal mesa shape irrespective of the orientation of the crystals on the surface of the semiconductor substrate. For this purpose, the invention also provides a novel method of manufacturing a semiconductor device using a new wet etching solution having an etching rate for a portion below the etching mask higher than that in the direction of the depth of the semiconductor substrate.

The basic constitution of the semiconductor device according to the invention is as described below. That is, the semiconductor device of the invention comprises at least a zinc blende type single crystal semiconductor substrate and a semiconductor active region formed in or on the zinc blende type single crystal semiconductor in which the zinc blende type single crystal semiconductor substrate is formed with a hole or a step in at least one surface thereof. Then, the hole or the step is shaped have a slope in which each angle formed at a corner between the surface left without forming a hole in a crystal plane formed with the hole or the step and the lateral surface of the hole is larger than 90°.

In a practical embodiment of the semiconductor device according to the invention, the lateral surfaces of the hole or the step in the etching direction parallel with the bottom of the zinc blende type single crystal semiconductor substrate include lateral surfaces crossing each other that are asymmetrical in shape.

In another practical embodiment of the semiconductor device according to the invention, the hole or the step is a rectangular shape, and the lateral surfaces in the etching direction parallel with the bottom of the zinc blende type single crystal semiconductor substrate include the lateral surfaces crossing each other that are asymmetrical in shape.

In another practical embodiment of the semiconductor device according to the invention, the lateral surfaces of the hole or the step in the etching direction parallel with the bottom of the zinc blende type single crystal semiconductor substrate are such that one of the lateral surfaces crossing to each other has an angle of 54.7° or less and the other of the lateral surfaces is more abrupt than the lateral surface of 54.7° or less. The angle of 54.7° or less is, more exactly, 54.7° as described above. The angle means herein a practical angle in the actual step. Accordingly, in another point of view, the angle means that the so-called normal mesa plane, in the present specification, is a plane shallower than the {111} A plane. This means that the angle formed between the hole or the normal mesa plane and the {111} A plane is 54.7° or less. The angular range described below has the same meanings.

In another practical embodiment of the semiconductor device according to the invention, a hole or a step is formed in a (100) plane of the zinc blende type single crystal semiconductor substrate, and the hole or the step has a normal mesa shape in which the average angle formed between the surface from the opening to the bottom of the hole or the step (that is, the lateral surface of the hole) and the left (100) plane is larger than 125.30, in the cross section as viewed from a (011) plane vertical to the (100) plane or a plane parallel with the (011) plane, and a cross section as viewed from a (01-1) plane vertical to the (100) plane and the (011) plane or a plane parallel with the (01-1) plane.

A semiconductor device in another point of view of the invention has the following configuration. That is, the semiconductor device in another point of view of the invention comprises at least a zinc blende type single crystal semiconductor substrate, and a semiconductor element portion mounted on a first crystal plane of the semiconductor substrate. Then, the semiconductor substrate comprises a hole or a step penetrating the semiconductor substrate and including at least a portion of a region facing the semiconductor element portion of a second crystal plane facing the first crystal plane of the semiconductor substrate, and the hole or the step is shaped to have a slope in which each angle formed at a corner between the surface left without forming the hole in the crystal plane formed with the hole or the step and the lateral surface of the hole is larger than 90°. Then, a conductor layer is provided which is connected electrically by way of the hole penetrating the semiconductor substrate to the semiconductor element portion.

A typical example of the semiconductor element portion mounted on the first crystal plane of the semiconductor substrate is a heterojunction transistor. Further, the semiconductor element portion can use, depending on the demand, for example, power amplifiers, various semiconductor devices using FET, or optical semiconductor devices. Typical examples of the optical semiconductor devices include, for example, an APD (Avalanche Photo-Diode).

A method of manufacturing a semiconductor device according to the invention includes at least the steps of forming a resist film having an opening of a desired shape over a zinc blende type single crystal semiconductor substrate, and etching the thus prepared semiconductor substrate by use of an etching solution by impregnating the semiconductor substrate with the etching solution along the boundary between the resist film and the semiconductor substrate, thereby forming the cross section of the opening into a mesa shape in any etching direction in the opening.

Then, a typical example of the step of forming the cross section of the opening into the mesa shape is a step of applying etching by using an etching solution containing an acid, aqueous hydrogen peroxide and alcohols. Further, in another example, etching is applied by using an etching solution containing an acid, aqueous hydrogen peroxide and a surface active agent.

### BRIEF DESCRIPTION OF THE DRAWINGS

FIGS. 1A and 1B are cross-sectional views of a hole in a group III-V single crystal semiconductor substrate used for a semiconductor device according to the present invention;

FIG. 2 is a perspective view showing a relation between the shape of a hole and the crystal orientation of a group III-V single crystal semiconductor substrate formed by an existent wet etching solution;

FIG. 3 is a cross-sectional view of a hole formed in a (100) plane of a group III-V single crystal semiconductor substrate with an existent wet etching solution as viewed from a (01-1) plane;

FIG. 4 is a cross-sectional view of a hole formed in a (100) plane of a group III-V single crystal semiconductor substrate with an existent wet etching solution as viewed from a (011) plane;

FIG. 5 is a cross-sectional view of a semiconductor substrate of the invention by way of example;

FIG. 6 is a schematic cross sectional view for explaining the etching state, as viewed from a (01-1) plane, of the hole in a group III-V single crystal semiconductor substrate used in a semiconductor device of the invention;

FIG. 7 is a schematic cross-sectional view of explaining the etching state, as viewed from (011) plane, of the hole in a group III-V single crystal semiconductor substrate used in the semiconductor device of the invention;

FIG. 8 is a cross-sectional view showing detailed shape, as viewed from a (01-1) plane, of the hole in a group III-V single crystal semiconductor substrate used in the semiconductor device of the invention;

FIG. 9 is a cross-sectional view showing detailed shape, as viewed from a (011) plane for the hole in a group III-V single crystal semiconductor substrate used in the semiconductor device of the invention;

FIG. 10 is a vertical cross-sectional structural view of an HBT having a heat dissipation hole disposed immediately therebelow used in a semiconductor device as an embodiment of the invention;

FIG. 11 is a cross-sectional view of a semiconductor device shown in the order of manufacturing steps for the HBT according to an embodiment of the invention;

FIG. 12 is a cross-sectional view of the semiconductor device shown in the order of manufacturing steps for the HBT according to the embodiment of the invention;

FIG. 13 is a cross-sectional view of the semiconductor device shown in the order of manufacturing steps for the HBT according to the embodiment of the invention;

FIG. 14 is a cross-sectional view of the semiconductor device shown in the order of manufacturing steps for the HBT according to the embodiment of the invention;

FIG. 14 is a cross-sectional view of the semiconductor device shown in the order of manufacturing steps for the HBT according to the embodiment of the invention;

FIG. 16 is a cross-sectional view of the semiconductor device shown in the order of manufacturing steps for the HBT according to the embodiment of the invention;

FIG. 17 is a cross-sectional view of the semiconductor device shown in the order of manufacturing steps for the HBT according to the embodiment of the invention;

FIG. 18 is a cross-sectional view of the semiconductor device shown in the order of manufacturing steps for the HBT according to the embodiment of the invention;

FIG. 19 is a cross-sectional view of the semiconductor device shown in the order of manufacturing steps for the HBT according to the embodiment of the invention;

FIG. 20 is a cross-sectional view of the semiconductor device shown in the order of manufacturing steps for the HBT according to the embodiment of the invention;

FIG. 21 is a cross-sectional view of the semiconductor device shown in the order of manufacturing steps for the HBT according to the embodiment of the invention;

FIG. 22 is a cross-sectional view of the semiconductor device shown in the order of manufacturing steps for the HBT according to the embodiment of the invention;

FIG. 23 is a cross-sectional view of the semiconductor device shown in the order of manufacturing steps for the HBT according to the embodiment of the invention;

FIG. 24 is a cross-sectional view of the semiconductor device shown in the order of manufacturing steps for the HBT according to the embodiment of the invention;

FIG. 25 is a cross-sectional view of the semiconductor device shown in the order of manufacturing steps for the HBT according to the embodiment of the invention; and

FIG. 26 is a cross-sectional view of the semiconductor device shown in the order of manufacturing steps for the HBT according to the embodiment of the invention.

### DESCRIPTION OF PREFERRED EMBODIMENTS

Before explaining concrete embodiments of the semiconductor device, descriptions are to be made of a method of forming a hole or a step in a normal mesa shape irrespective of the crystal orientation of a substrate crystal concerning the present invention.

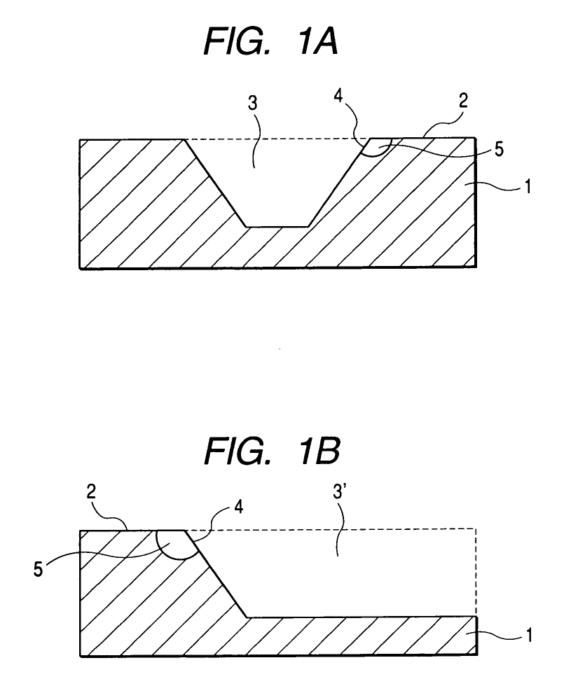

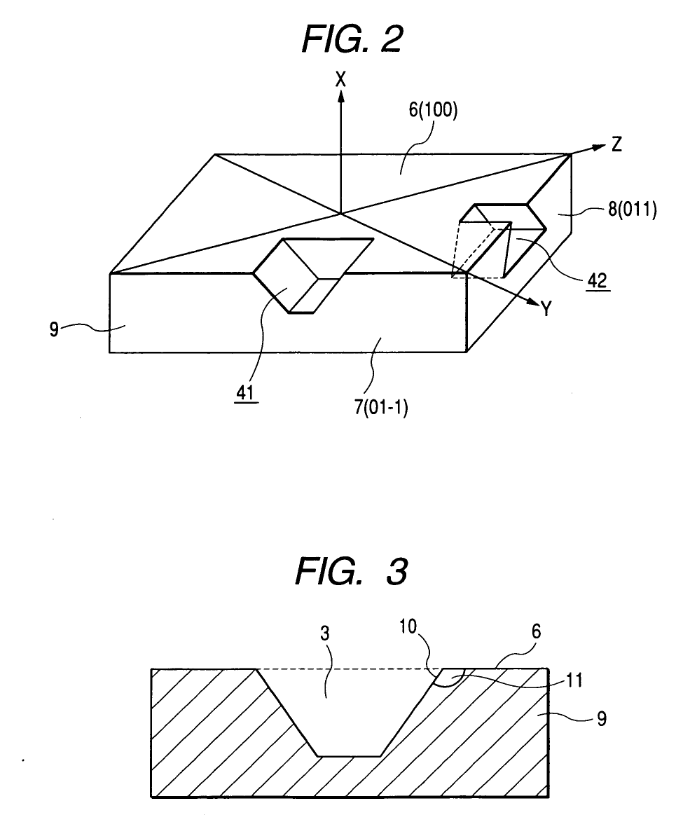

FIGS. 1A and 1B are cross-sectional views of a hole and a step in a semiconductor device having the hole and the step of a normal mesa shape, respectively, in a semiconductor substrate of the invention. FIG. 1A shows an example having a hole 3 in a substrate 1 and FIG. 1B is an example having a hole 3′ in a substrate 1. The hole 3 of a normal mesa shape is formed in one surface of a group III-V single crystal semiconductor substrate 1, while a semiconductor active element is formed on another surface or on the same surface. The normal mesa shape has an angle 5 of greater than 90° formed at a corner between a substrate surface 2 and a lateral surface 4 of the hole. Unlike the example of FIG. 2, the invention has a feature that the hole 3 has a normal mesa shape when observed at any cross section so long as it is vertical to the substrate surface.

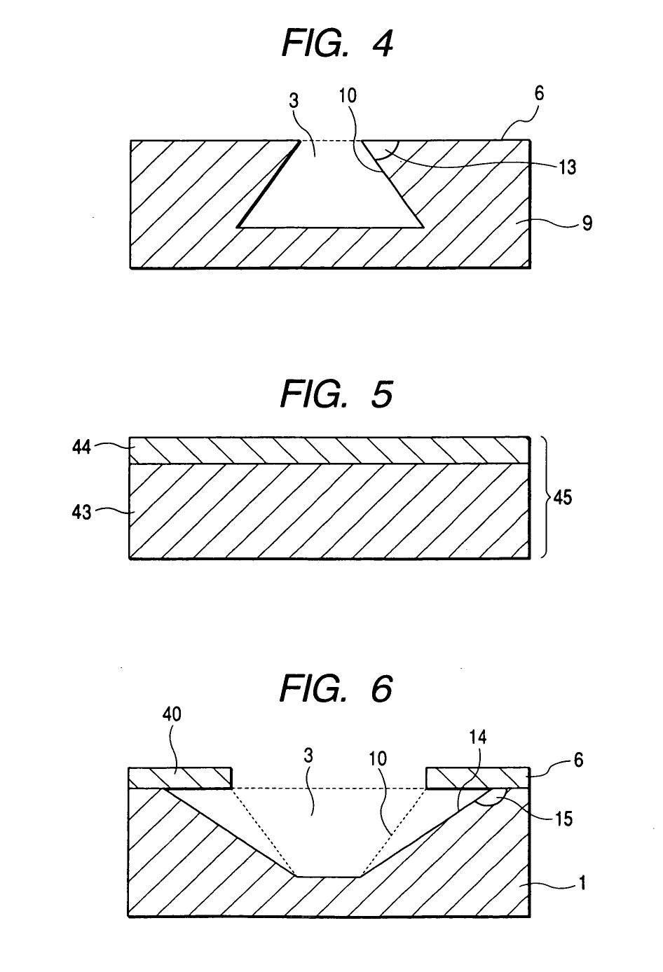

In a case of using dry etching in the hole forming step, the angle is substantially vertical, that is, about 90°. Further, in a case of forming a hole by using the existent wet etching solution, etching is stopped at a {111} A plane. Accordingly, the normal mesa shape and the inverted mesa shape are developed depending on the crystal orientation and the angle is smaller than 90° when viewed at a certain cross-section. FIGS. 3 and 4 show cross-sectional shapes by way of existent example when holes are formed in a GaAs (100) plane.

On the contrary, the inverted mesa shape is not developed for the hole in the invention when observed at any cross-section. According to this embodiment, in forming a semiconductor device on a group III-V single crystal semiconductor substrate, it is no more necessary to consider the difference of the hole shape depending on the crystal orientation, whereby the degree of freedom in the layout is improved greatly. Further, since all of the holes are in the normal mesa shape, disconnection does not occur in a case of forming an electrode or the like on the hole or the step. Further, worry of bursting caused by residual air in a case of filling a conductive substrate such as a silver paste in the hole for connection with a module substrate or the like is eliminated, improving reliability.

In the invention, it is important to form such a normal mesa shape irrespective of the crystal orientation. A typical example of the group III-V single semiconductor substrate served for a semiconductor device is a GaAs substrate or an InP substrate. Further, a semiconductor substrate in which a semiconductor epitaxial layer is formed on the surface of the GaAs substrate or the InP substrate may also be used depending on the purpose. In the present specification, single semiconductor substrates and semiconductor substrates formed with the epitaxial layers are collectively referred to as “semiconductor substrate”. FIG. 5 is a cross sectional view showing an example of a semiconductor substrate 45 in which an epitaxial layer 44 is formed on a crystal growing semiconductor substrate 43. The semiconductor substrate is usually used with a (100) plane as the main plane. The crystal plane generally has a likelihood value of about ±2 degrees.

The group III-V compound semiconductor substrate crystal has a zinc blende type structure. In a case of forming an etching mask of a desired shape on the compound semiconductor crystal described above and forming a hole or a step by wet etching, the form of the invention can be attained by etching using an etching solution incorporated with alcohols and a surface active agent. The etching mask may be a resist used in the field of semiconductors. The resist is a photoresist comprising an organic polymeric resin material and both of positive or negative types may be used depending on the requirement. A mask made of an inorganic material such as WSi or SiO₂ is not suitable for the etching mask. Since the inorganic mask bonds more firmly to the semiconductor substrate compared with the resist, etching proceeds mainly to the inside of the substrate. Accordingly, etching is stopped at the {111} plane as described above and both the normal mesa and inverted mesa shapes are developed.

An etching solution constituting a base for the etching solution of the invention may be a usual etching solution used for the compound semiconductor crystal. A typical example of the etching solution used customarily to the compound semiconductor crystals can include, for example, a mixed solution of an acid, for example, a hydrofluoric acid or sulfuric acid, hydrogen peroxide and water. The open hole of the normal mesa shape of the invention can be obtained by adding alcohols or a surface active agent to such a usual etching solution described above. Typical examples of the alcohols include isopropyl alcohol, ethanol and methanol. EMAL (trade name of product) is especially suitable as the surface active agent. The composition of the etching solution is determined depending on the conditions such as the composition and the thickness of the semiconductor crystal as an object of etching, and the depth of the hole, etc. If the alcohols or the surface active agent is added less than 20% by volume to the etching solution as a mixture of the acid and aqueous hydrogen peroxide, the effect intended in the invention cannot be obtained. On the other hand, if it exceeds 50%, the photoresist for use in the existent etching mask material is damaged undesirably. As has been described above, the addition amount is preferably from 35% to 40% by volume based on the etching solution although it depending on the conditions for the object to be etched. Circumstantial conditions such as etching temperature and etching time may be determined in accordance with usual conditions regarding the manufacture of the semiconductor devices, although it may depend on the conditions of fabrication.

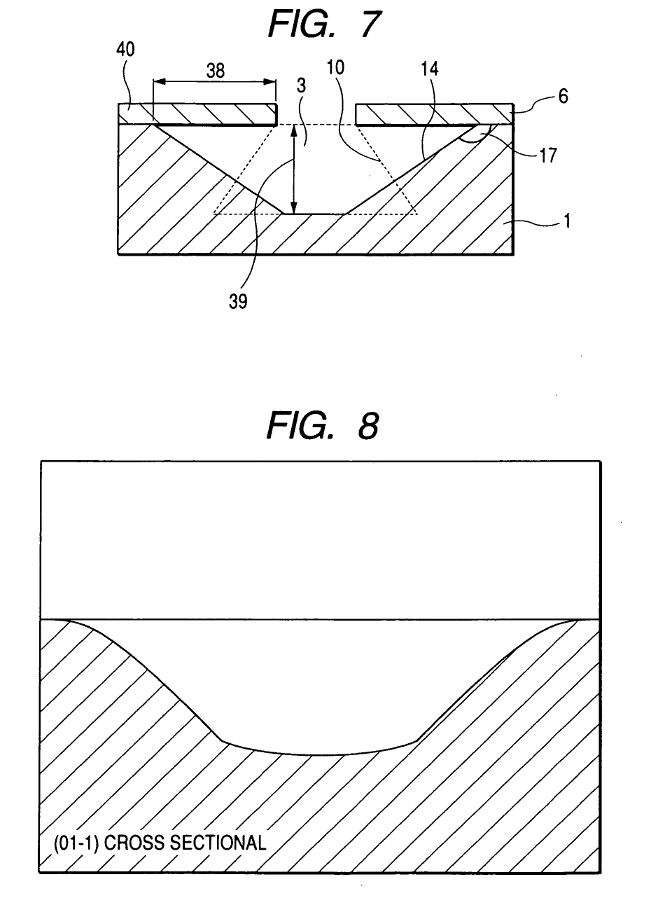

It may be said that the etching method according to the invention described above is a method of conducting etching along the boundary between the etching mask and the compound semiconductor crystal while impregnating the compound semiconductor crystal with the etching solution along with the progress of etching and applying etching in the mesa shape in each of etching directions. That is, the manufacturing method of the invention utilizes the nature that side etching proceeds at a higher rate in the vicinity of the boundary between the substrate and the mask than the wet etching proceeds toward the inside of the substrate, by using the etching situation containing the alcohols and the resist mask. This will be described more specifically with reference to FIGS. 6 and 7.

FIGS. 6 and 7 are views for explaining the etching state in the invention. In both the drawings, reference 1 denotes a semiconductor substrate and 40 denotes a photoresist.

FIG. 6 is a schematic cross sectional view of a hole as viewed from a (01-1) plane vertical to a (100) plane of a group III-V single crystal semiconductor. A hole 3 is formed in the (100) plane, and it has a feature in that an average angle 15 formed between the lateral surface 14 of the hole as a surface from the opening to the bottom of the hole, and the outside of the hole opening, that is, the left (100) plane 6 is larger than 125.3° as the angle formed between the (100) plane 6 and a (111) A plane 10. In the hole forming step, when wet etching with the existent etching solution is adopted, etching is stopped at the {111} A plane 10 shown by a broken line (small dot broken line) in the drawing. That is, in a case of applying wet etching by using an existent etching solution comprising an acid and hydrogen peroxide not containing alcohols and a resist mask, etching proceeds mainly toward the inside of the substrate and the etching is stopped at the {111} plane A as described above to develop both the shapes of normal mesa and inverted mesa.

However, in the etching according to the invention, the hole opening is extended more for the same bottom area and depth of the hole, as shown by a solid line 14. That is, in the case of using the etching solution containing the alcohols and the resist mask, since side etching proceeds in the vicinity of the mask boundary at etching power stronger than power for stopping the etching at the {111} A plane, the widening extent 38 of the hole is larger than the depth 39 of the hole, in which the inverted mesa shape does not develop but the normal mesa shape are developed at all of the planes. In addition, the average angle formed between the lateral surface of the hole and the surface left unetched below the mask is larger than 125.3° that represents the {111} A plane. According to this embodiment, all the holes can be formed into the normal mesa shape by using an easily available resist mask and merely adding alcohols to the existent etching solution containing acid and hydrogen peroxide.

However, the angle at the lateral surface of the hole is not always constant but the angle near the hole opening sometimes larger than that near the bottom of the hole. FIG. 8 is a view showing an actual example of the cross section as viewed from the (01-1) plane.

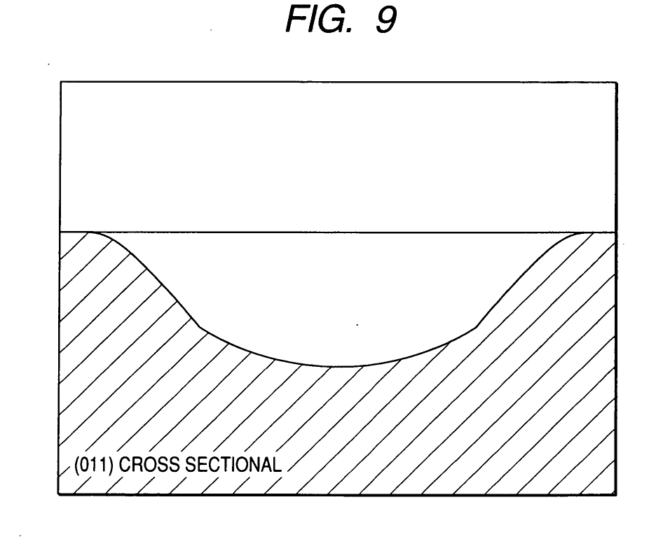

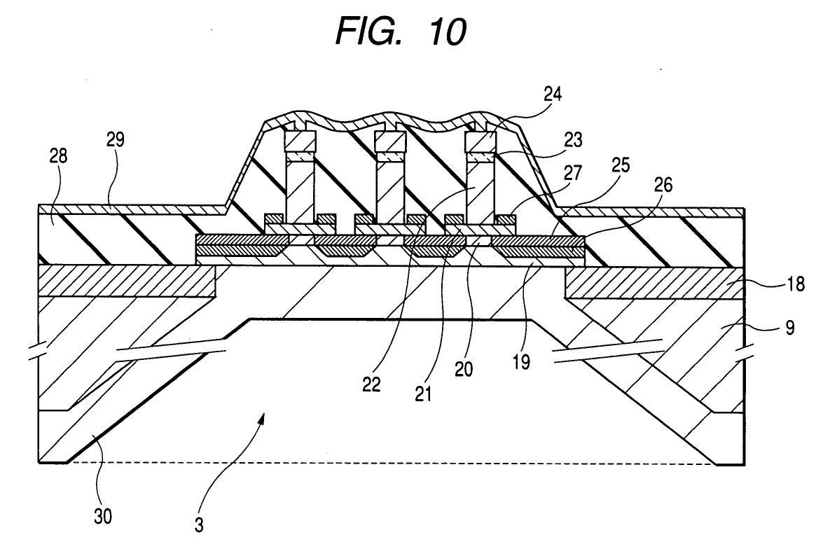

Further, FIG. 7 shows a schematic cross sectional shape of a hole as viewed from the (011) plane vertical to the (100) plane and the (01-1) plane. In a case of using wet etching with the existent etching solution, etching is stopped at the {111} plane A 10 shown by the broken line (broken line with small dots) in the drawing to develop the inverted mesa shape. However, in the etching according to the invention, a normal mesa shape is developed as shown by the solid line 14 in the etching according to the invention and, further, the average angle 17 formed between the surface outside the hole opening, that is, the left (100) plane 6 and the lateral surface 14 is larger than 125.3°. FIG. 9 is a view showing an actual example of the cross section as viewed from the (011) plane.

Then, the lateral extension of the normal mesa shape to the substrate surface described above shows that the etching solution is impregnated as etching proceeds along the boundary between the etching mask and the compound semiconductor crystal. Accordingly, while the paired cross-sectional shapes in both directions have the same normal mesa shape, they are different from each other in an actual detailed shape. That is, a pair of lateral surfaces in the etching direction is asymmetrical to each other. Generally, the paired lateral surfaces in the etching direction have an angle of 54.7° or less, whereas the other paired lateral surfaces form a more acute angle.

Then, a description is to be made of an embodiment of a semiconductor device using a collector top HBT according to the invention. FIG. 10 is a vertical cross sectional structural view. The semiconductor device is constituted by using a collector top HBT having a heat dissipation hole of a normal mesa shape as a third embodiment of the invention.

A collector top HBT is formed on a (100) plane of a semi-insulative GaAs substrate 9 as a group III-V single crystal semiconductor, while a hole 3 of a normal mesa shape in which an angle formed at the corner between the substrate surface and the lateral surface of the hole is larger than 90° like in the first embodiment is formed on a substrate below the HBT. On a semi-insulative GaAs substrate 9, are formed an InGaP buffer layer (InP molar ratio increasing gradually from 0.5 to 1.0, undoped, layer thickness of 1.5 μm) 18, highly doped n-type InGaAs sub-emitter layer (InAs molar ratio of 0.5, Si concentration at 4×10¹⁹ cm⁻³, layer thickness of 0.6 μm) 19, an n-type InAlAs emitter layer (InAs molar ratio of 0.5, Si concentration at 5×10¹⁷ cm⁻³, layer thickness of 0.2 μm) 20, a p-type GaAsSb base layer (GaAs molar ratio of 0.5, C concentration at 3×10¹⁹ cm⁻³, layer thickness of 70 nm) 21, an n-type InP collector layer (Si concentration at 3×10¹⁶ cm⁻³, layer thickness of 0.8 μm) 22, and n-type InGaAs cap layer (InAs molar ratio of 0.5, Si concentration at 4×10¹⁹ cm⁻³, layer thickness of 0.2 μm) 23, in which a collector electrode 24 and a base electrode 27 are formed in a non self-alignment manner. The collector electrode 24 and the base electrode 27 may of course be formed with the so-called self-alignment manner. In the transistor parasitic region in the emitter layer and the sub-emitter layer 19 (a region other than the HBT intrinsic area just below the collector electrode 24), a high resistance InAlAs parasitic emitter region 25 and an n-type AlAs parasitic emitter region 26 implanted with boron ions are formed, which minimizes the base current flowing through the parasitic emitter base junction. The ions to be implanted may be helium, oxygen, fluorine, or a combination thereof in addition to boron, by which the high resistance region 25 and n-type region 26 are formed in the same manner.

The GaAs substrate 9 and the InGaP buffer layer 18 just below the HBT and including intrinsic region are removed, and an emitter electrode 30 is formed, just below the HBT, in contact with the highly doped n-type InGaAs sub-emitter layer 19.

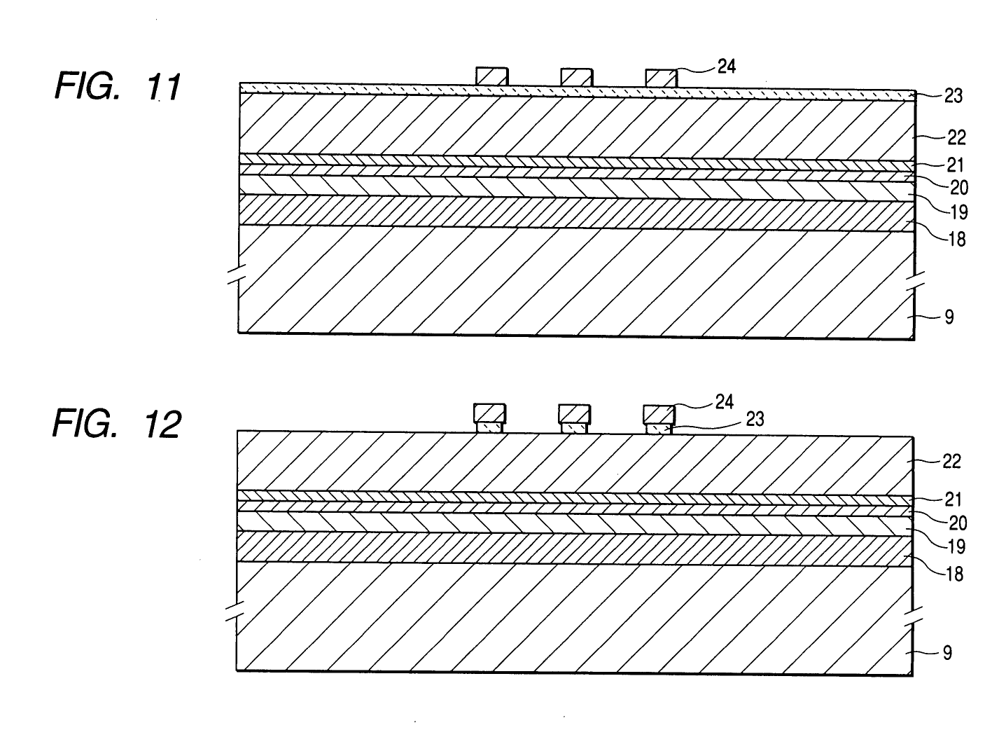

A method of manufacturing a collector top HBT having the heat dissipation hole shown in FIG. 10 will then be described with reference to FIGS. 11 to 26. At first, an InGaP buffer layer 18, a highly doped n-type GaAs sub-emitter layer 19, an n-type InAlAs emitter layer 20, a p-type GaAsSb base layer 21, an n-type InP collector layer 22, and an n-type InGaAs cap layer 23 are successively grown epitaxially on a semi-insulative GaAs substrate 9 by using an organo metal gas phase epitaxy or molecular beam epitaxy. Then, WSi (Si molar ratio of 0.3, layer thickness of 0.3 μm) is deposited over the entire wafer surface using a high frequency sputtering method, and a collector electrode 24 is formed by photolithography and dry etching using CF₄ (FIG. 11).

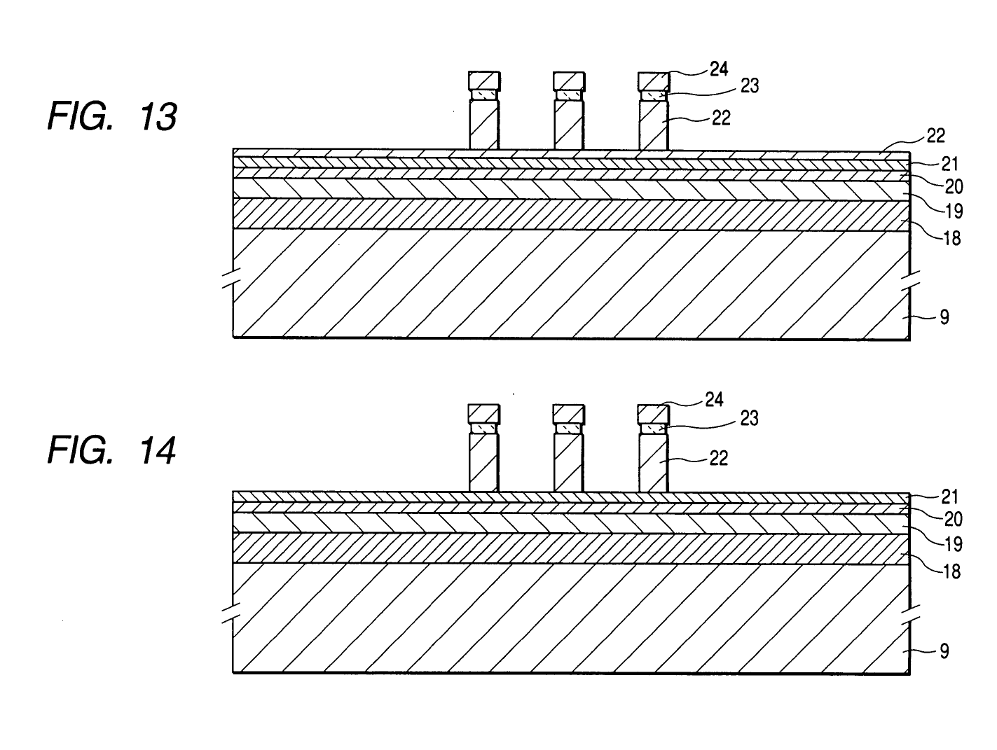

Then, the n-InGaAs cap layer 23 is wet etched using a mixed solution of phosphoric acid, aqueous hydrogen peroxide and water using the region of the collector electrode 14 as a mask to form an undercut of 0.3 μm (FIG. 12). Then, the n-InP collector layer 22 is etched by 0.7 μm by dry etching using CF₂ and Cl₂ (FIG. 13).

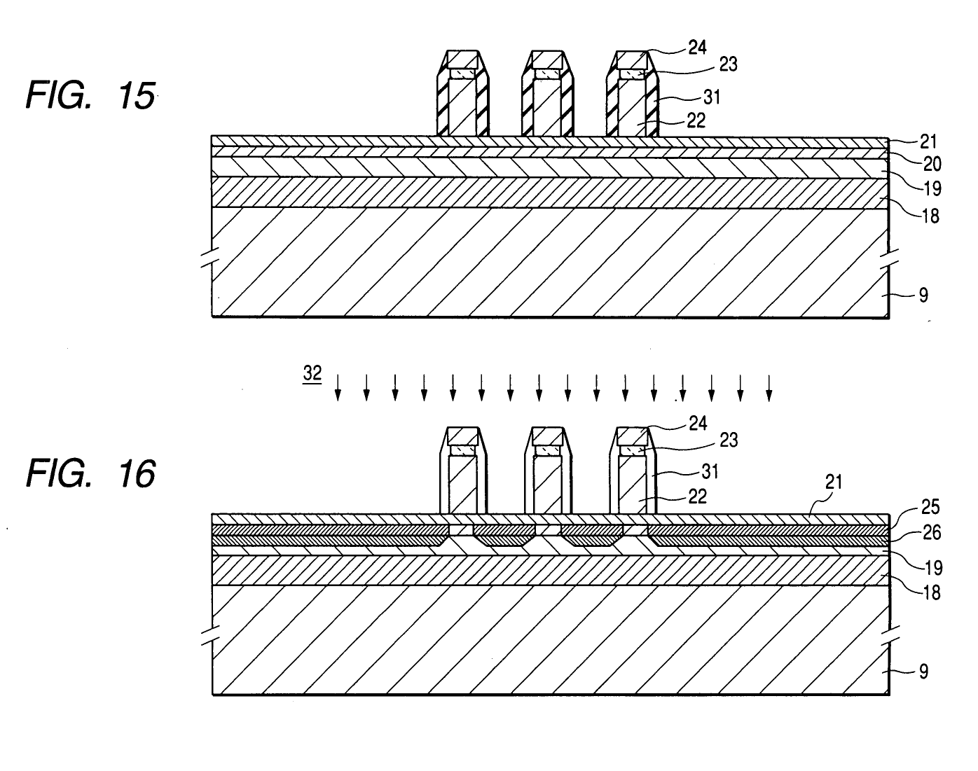

The n-type InP collector 22 is then removed by wet etching using an aqueous solution of hydrochloric acid (FIG. 14). In this step, the p-type GaAsSb layer 21 is not etched with the aqueous solution of hydrochloric acid, and the surface of the p-type GaAsSb layer 21 is exposed. In addition, an undercut of about 0.3 μm width corresponding to the amount of side etching upon wet etching of the n-type InGaAs cap layer 23 is formed on the n-type InP collector layer 22. Thereafter, an SiO₂ film (layer thickness of 400 nm) is deposited at 390° C. using a heat decomposing chemical vapor phase deposition method and a SiO₂ side wall 31 is fabricated by dry etching using C₂F₆ and CHF₃ (FIG. 15). Successively, boron ions 32 are implanted at room temperature under the conditions of an acceleration energy of −50 Kev, an incident angle 0° and a dose of 2×10¹² cm⁻² using the region of the collector electrode 24 and the SiO₂ side wall 31 as a mask. In this case, crystal defects formed by ion implantation diffuse laterally and the high resistance InAlAs parasitic emitter region 25 extends laterally (FIG. 16). The extending width is further widened by the heat treatment step in the subsequent manufacturing steps and, after the completion of the device manufacturing steps, it is estimated at about 0.3 to 0.5 μm in view of the collector mesa size dependence of the collector current. The n-type InGaAs parasitic sub-emitter region 26 also extends laterally like the high resistance InAlAs parasitic emitter area 25; however, since the resistance of InGaAs is not increased by ion implantation and the n-type conduction is maintained, the n-type InGaAs parasitic sub-emitter 26 poses no problem with the HBT operation.

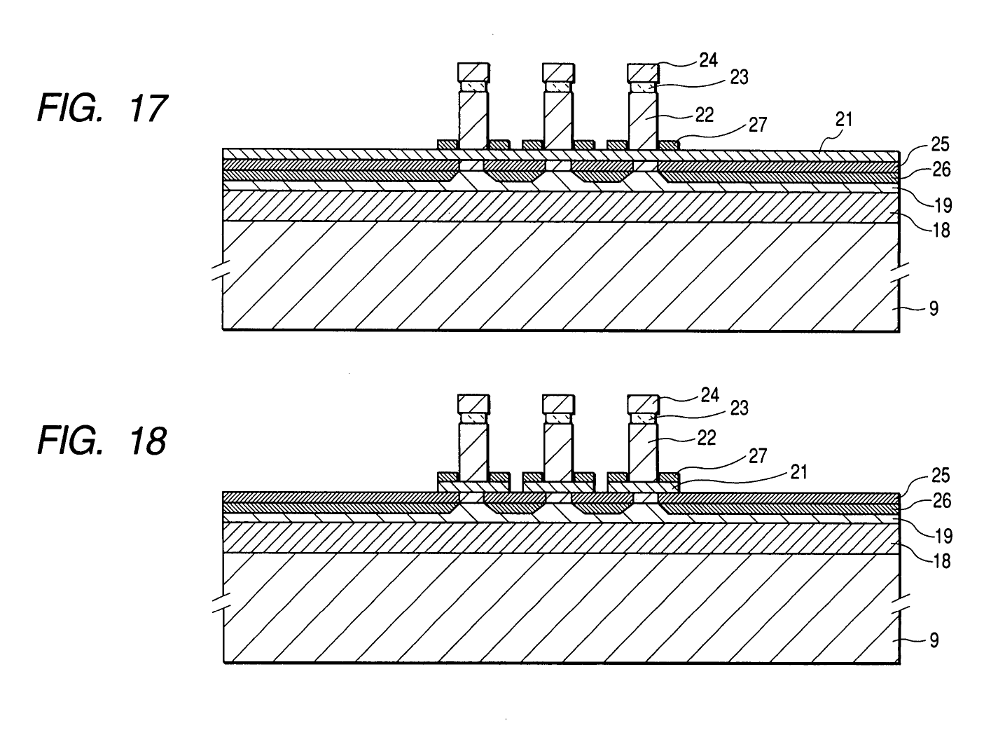

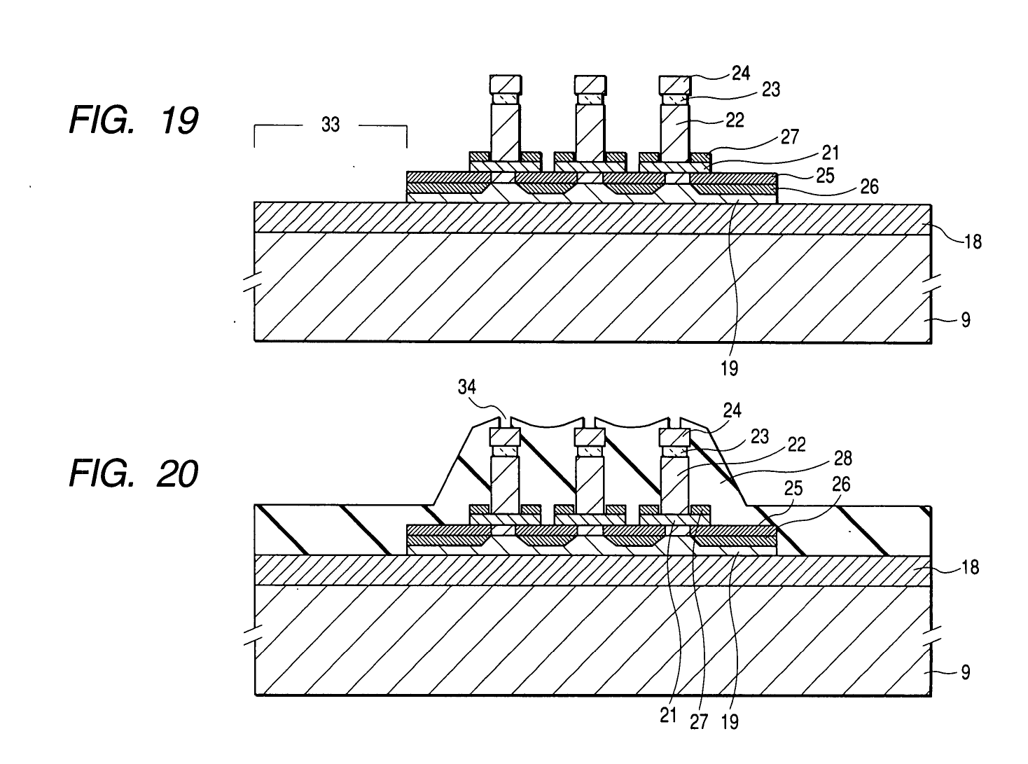

Then, the SiO₂ sidewall 31 is removed using an aqueous solution of hydrofluoric acid, and a base electrode Pt (20 nm)/Ti (50 nm)/Pt (50 nm)/Au (200 nm)/Mo (20 nm) 27 is formed by a lift-off method using electron beam vapor deposition (FIG. 17). Then, the p-type GaAsSb base layer 21 is removed using the base electrode 27 as a mask by using photolithography and argon ion milling, to expose the high resistance InAlAs parasitic emitter region 21 (FIG. 18). Then, the sub-emitter layer 19 in the interconnection device isolation region 33 is removed to expose the surface of the buffer layer 18 by photolithography and wet etching using a mixed solution of phosphoric acid, hydrogen peroxide and water (FIG. 19).

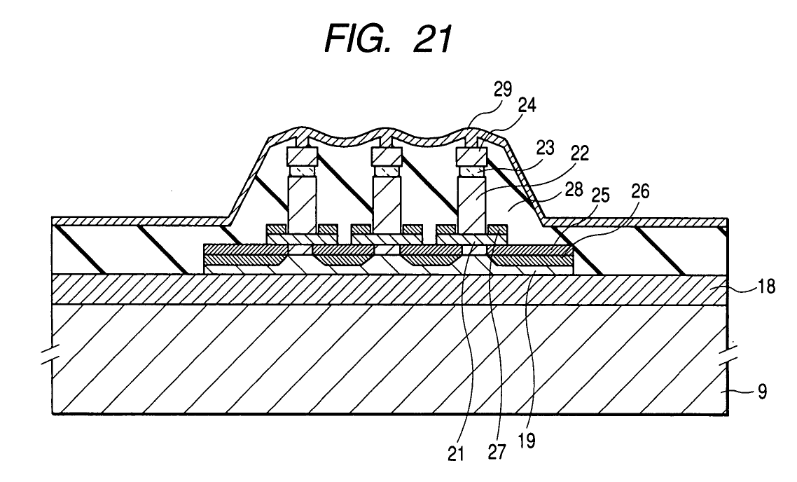

Then, an SiO₂ film (film thickness of 0.5 μm) 28 is deposited at 250° C. by a plasma excited chemical vapor deposition method, base contact holes for connecting base electrode and interconnection are formed, Mo (film thickness of 0.15 μm)/Au (film thickness of 0.8 μm)/Mo (film thickness of 0.15 μm) is entirely deposited as a first layer interconnection metal, and base interconnection by photolithography and argon ion milling are conducted (since the base interconnection is perpendicular to the surface of the drawing sheet and present in the HBT parasitic region, it is not illustrated). Then, SiO₂ film (film thickness 0.5 μm) is deposited at 250° C. by a plasma excite chemical vapor phase deposition method again and collector contact holes 34 for connecting the collector electrode 24 and the interconnections are formed (FIG. 20). Successively, an Mo (film thickness of 0.15 μm)/Au (film thickness of 0.8 μm) as a second layer interconnection metal is deposited over the entire surface, and a collector interconnection 29 is formed by photolithography and argon ion milling (FIG. 21).

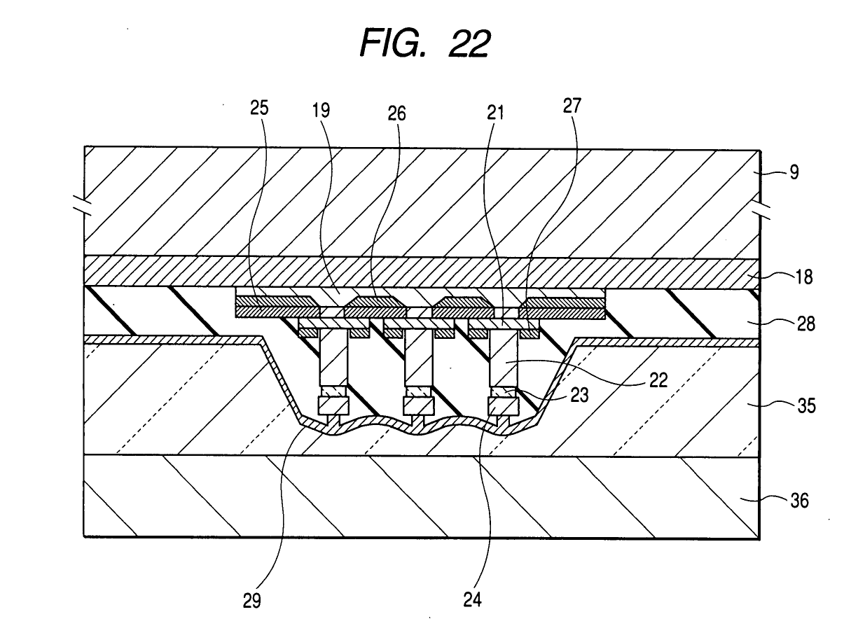

Then, an adhesive 35 is coated over the entire wafer surface, and appended on a glass substrate 36 (FIG. 22). Then, after curing the adhesion by heating at 150° C., the thickness of the GaAg substrate is reduced to 50 μm.

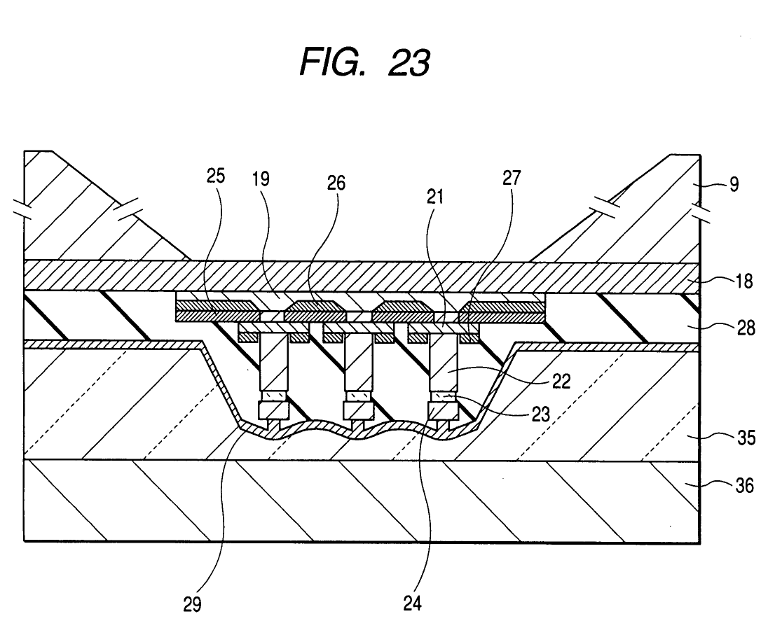

Successively, the substrate at a region including the HBT intrinsic region is removed such that the angle formed at the corner between the substrate surface and the lateral surface of the hole was larger than 90° by photolithography and dry etching or wet etching, or the etching as a combination thereof to form a heat dissipation hole of a normal mesa shape (FIG. 23). In this step, etching was stopped at the lower surface of the InGaP buffer layer 18. In a case of using wet etching, an etching solution containing the acid, aqueous hydrogen peroxide and alcohols described above is suitable. Hydrofluoric acid and sulfuric acid are typical examples of the acid as described above. The etching solution is preferably, by way of example, a solution comprising hydrofluoric acid, aqueous hydrogen peroxide, sulfuric acid, water and isopropyl alcohol at the mixing ratio, for example, of [4 to 6]:[5 to 10]:[8 to 25]:[30 to 45]:[balanced at 20 or more], respectively, at a ratio of % by volume. Further, an etching solution containing an acid, aqueous hydrogen peroxide and a surface active agent can also be used.

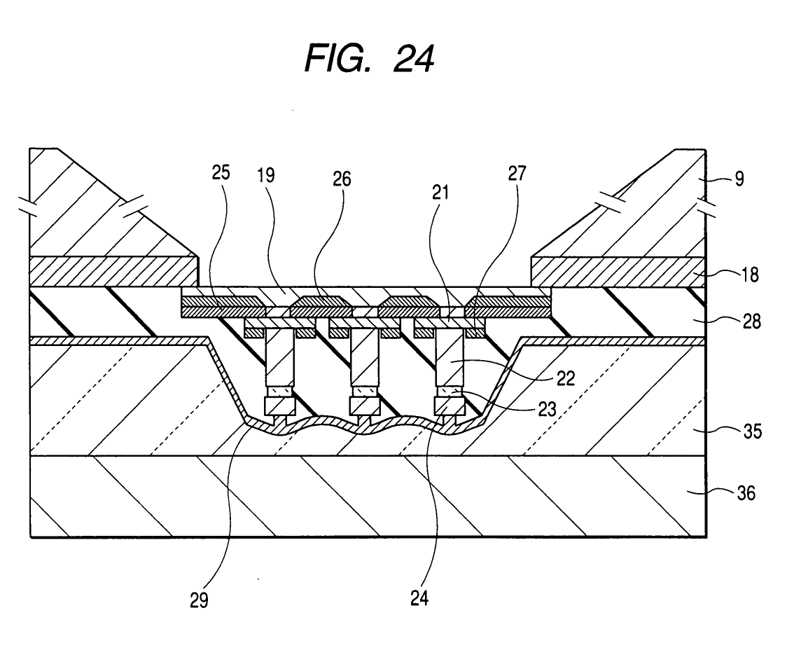

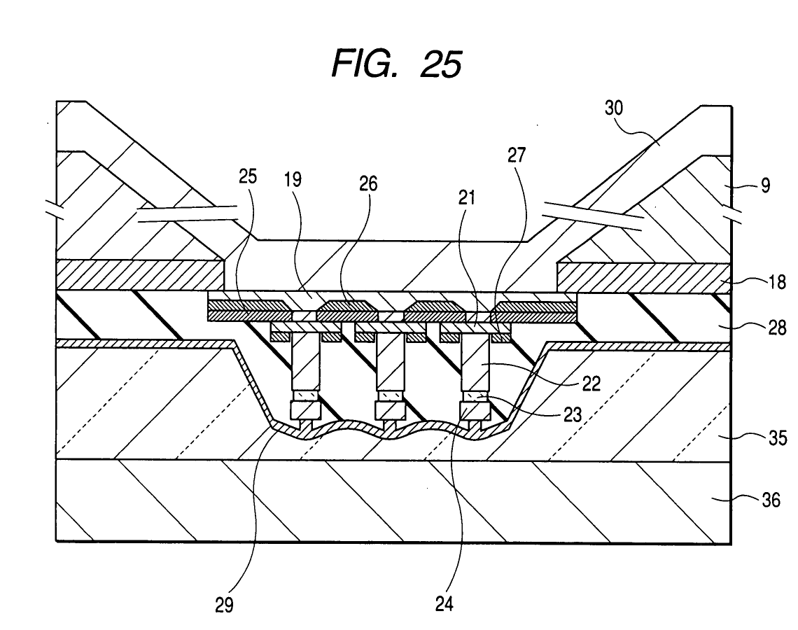

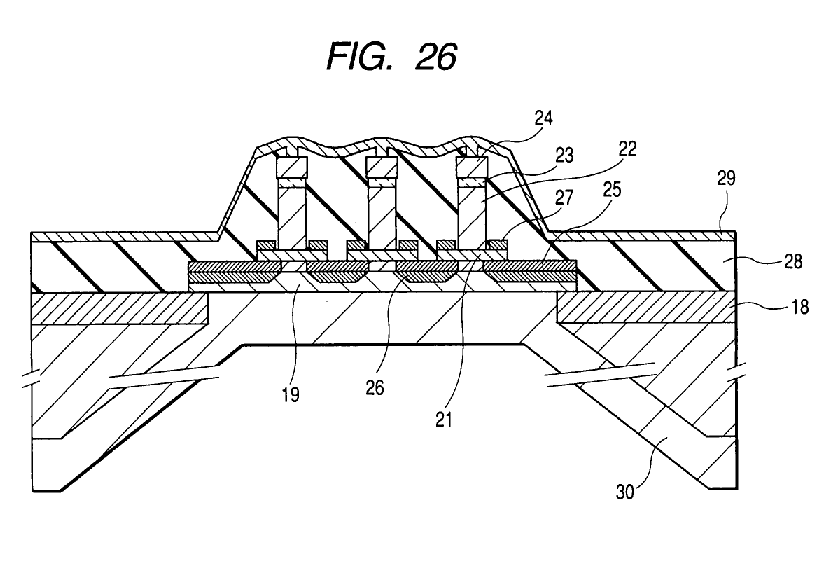

Then, the InGaP buffer layer 18 is removed by using an aqueous solution of hydrochloric acid to expose the lower surface of the InGaAs sub-emitter layer 19 (FIG. 24). Finally, Ti (film thickness of 50 nm)/Pt (film thickness of 50 nm)/Au (film thickness of 300 nm) are deposited by sputtering over the entire rear face of the substrate, a rear face emitter electrode 30 is deposited by Au plating (film thickness of 3 μm) (FIG. 25), and the adhesive 35 is removed to prepare a collector top HBT having a dissipation hole (FIG. 26).

According to this embodiment, since all the heat dissipation holes formed are in the normal mesa shape, when the emitter electrode is formed so as to cover the holes, disconnection does not occur. Further, also in a case of filling a conductive substance such as a silver paste in the heat dissipation hole and bonding to the module substrate or the like for emitter grounding, worry of bursting caused by the residual air can be eliminated to provide an effect of improving reliability. While a heat dissipation hole is formed for several collective HBTs in the figures, one heat dissipation hole may be formed below each HBT to produce the same effect. Further, while the collector top HBT has been referred to in this embodiment, the emitter top HBT may be employed to produce the same effect.

Further, while the GaAs substrate is used, it is applicable also to the HBT using an InP substrate.

Also in a semiconductor device using the group III-V single crystal semiconductor such as FET or APD, an advantageous effect of improving the degree of freedom in the layout can be obtained in a case where normal mesa shapes are always developed irrespective of the crystal orientation.

According to the invention, worry of electrode disconnection caused by the step can be eliminated irrespective of the crystal orientation. Further, in a case of filling the conductive substance such as a silver paste in the hole and bonding to the module substrate, bursting caused by residual air no more occurs.

According to a first aspect of the invention, it is possible to provide a semiconductor device capable of overcoming the drawback due to the shape of the concave portion present in the zinc blende type compound semiconductor substrate in which the area of the bottom is larger than that of the surface in view of the cross sectional shape.

According to a second aspect of the invention, it is possible to provide a method of manufacturing a semiconductor device comprising a step capable of forming a concave portion of a shape in which the area of the surface is larger than that of the bottom in view of the cross sectional shape in a zinc blende type compound semiconductor irrespective of the crystal orientation.

Description of Reference Numerals

1: group III-V single crystal semiconductor substrate, 2: substrate surface, 3: hole, 4: lateral surface of hole at the opening, 5: angle formed between the substrate surface and the lateral surface of hole, 6: (100) plane, 7: (01-1) plane, 8: (011) plane, 9: GaAs substrate, 10: {111} plane A, 11: angle formed between (100) plane and {111} plane A as viewed from cross section (01-1), 13: angle between (100) plane and {111} plane A as viewed from cross section (011), 14: lateral surface of hole, 15: angle formed between (100) plane and the lateral surface of hole as viewed from cross section (01-1), 17: angle formed between (100) plane and the lateral surface of hole as viewed from cross section (011), 18: buffer layer 19: sub-emitter layer, 20: emitter layer, 21: base layer 22: collector layer, 23: cap layer, 24: collector electrode, 25: high resistance parasitic emitter region, 26: parasitic sub-emitter region, 27: base electrode, 28: insulative film, 29: interconnection, 30: rear face emitter electrode, 31: insulative film sidewall, 32: boron ion, 33: inter-device isolation region, 34: collector contact hole, 35: adhesive, 36: glass substrate, 37: resist mask, 38: extension of hole, 39: depth of hole.

1. A semiconductor device comprising:
a zinc blende type single crystal semiconductor substrate; and
a semiconductor active region formed on or over the zinc blende type single crystal semiconductor;
wherein the zinc blende type single crystal semiconductor substrate is formed with a hole or a step in at least one surface thereof, and
each corner angle between a side wall of the hole or the step and a crystal plane is larger than 90° when observed at any cross section.

2. A semiconductor device according to claim 1, wherein a shape of a first side wall of the hole or the step which is observed at the first cross-sectional view that is vertical to the zinc blende type single crystal semiconductor substrate is different from a shape of a second side wall which is observed at a second cross-sectional view intersecting the first cross-sectional view.

3. A semiconductor device according to claim 1, wherein the hole or the step is a rectangular shape, and a shape of a first side wall of the hole or the step which is observed at the first cross-sectional view that is vertical to the zinc blende type single crystal semiconductor substrate is different from a shape of a second side wall which is observed at a second cross-sectional view intersecting the first cross-sectional view.

4. A semiconductor device according to claim 2, wherein a first corner angle between a first side wall of the hole or the step and a crystal plane, when observed at a first cross-sectional view which is vertical to the zinc blende type single crystal semiconductor substrate, is 54.7° or less, and a second corner angle between a second side wall of the hole or the step, when observed at a second cross-sectional view which is vertical to the zinc blende type single crystal semiconductor substrate is more abrupt than the first corner angle.

5. A semiconductor device according to claim 1, wherein the zinc blende type single crystal semiconductor substrate comprises a group III-V compound semiconductor material.

6. A semiconductor device according to claim 1, wherein the zinc blende type single crystal semiconductor substrate is a crystal growing substrate.

7. A semiconductor device according to claim 1, wherein the zinc blende type single crystal semiconductor substrate has an epitaxial growing layer on a crystal growing substrate.

8. A semiconductor device according to claim 6, wherein the zinc blende type single crystal semiconductor substrate comprises a GaAs crystal or a InP crystal.

9. A semiconductor device according to claim 7, wherein the crystal growing substrate comprises a GaAs crystal or a InP crystal.

10. A semiconductor device according to claim 1, wherein the zinc blende type single crystal semiconductor substrate is formed with a hole or a step in a (100) plane thereof, and the hole or the step has a normal mesa shape in which an average angle formed between the side wall surface of the hole or the step and the (100) plane, from an opening portion to a bottom portion is larger than 125.3°, in a cross section as viewed from the (011) plane and as viewed from a (01-1) plane.

11. A semiconductor device comprising:
a zinc blende type single crystal semiconductor substrate; and
a semiconductor element portion mounted on a first crystal plane of the semiconductor substrate;
wherein the semiconductor substrate is formed with a hole or a step at a surface of a reverse side of the semiconductor element portion, and the hole or the step passes through the semiconductor element portion;
each corner angle between a side wall of the hole or the step and a crystal plane is larger than 90° when observed at any cross section; and
a conductor layer is provided which is connected electrically by way of the hole or the step penetrating the semiconductor substrate to the semiconductor element portion.

12. A semiconductor device according to claim 11, wherein the semiconductor element portion mounted on the first crystal plane of the semiconductor substrate is a heterojunction transistor.

13. A semiconductor device according to claim 12, wherein the heterojunction transistor has an emitter region on a side of the semiconductor substrate and a collector region disposed on a side opposite to the semiconductor substrate with the emitter layer being interposed therebetween.

14. A semiconductor device according to claim 11, wherein a shape of a first side wall of the hole or the step which is observed at the first cross-sectional view that is vertical to the zinc blende type single crystal semiconductor substrate is different from a shape of a second side wall which is observed at a second cross-sectional view intersecting the first cross-sectional view.

15. A semiconductor device according to claim 11, wherein the hole or the step is a rectangular shape, and a shape of a first side wall of the hole or the step which is observed at the first cross-sectional view that is vertical to the zinc blende type single crystal semiconductor substrate is different from a shape of a second side wall which is observed at a second cross-sectional view intersecting the first cross-sectional views.

16. A semiconductor device according to claim 11, wherein a first corner angle between a first side wall of the hole or the step and a crystal plane, when observed at a first cross-sectional view which is vertical to the zinc blende type single crystal semiconductor substrate, is 54.7° or less, and a second corner angle between another side wall of the hole or the step, when observed at a second cross-sectional view which is vertical to the zinc blende type single crystal semiconductor substrate is more abrupt than the first corner angle.
